(19) United States
(12) Patent Application Publication
(10) Pub. No.: US 2018/0115334 A1
(43) Pub. Date: Apr. 26, 2018

(54) IMPROVEMENTS TO SATELLITE TRANSMITTED DATA RECEIVING APPARATUS

(71) Applicant: Pro Brand International (Europe) Limited, Haslingden (GB)

(72) Inventor: Jonathan Walker, Reading, Aldermaston, Berkshire (GB)

(73) Assignee: Pro Brand International (Europe) Limited, Haslingden (GB)

(21) Appl. No.: 15/567,649

(22) PCT Filed: Apr. 21, 2016
(86) PCT No.: PCT/GB2016/051106

§ 371 Date: Oct. 19, 2017

(30) Foreign Application Priority Data
Apr. 21, 2015 (GB) 1506706.9

(51) Int. Cl. H04B 1/12; H05K 1/18; H05K 1/11; H05K 1/03; H05K 1/02; H05K 1/09; H03H 7/38; H05K 3/46; H04H 40/90

(52) U.S. Cl. CPC H04B 1/126; H05K 1/181; H05K 1/111; H05K 1/0366; H05K 1/0233; H05K 2201/10318; H03H 7/38; H05K 3/4644; H04H 40/90; H05K 2201/10166; H05K 2201/1006; H05K 1/09

(57) ABSTRACT

The invention relates to the provision of LNB apparatus alone and/or in conjunction with a waveguide which is provided to process received data signals which are broadcast using satellite transmission systems. The wanted data signals are passed along at least two paths formed on the printed circuit board structure provided in the LNB. The printed circuit board structure includes at least one integrated circuit with an image rejection mixer or direct conversion mixer which allow the filtering out of the unwanted frequency bands from the received data. The printed circuit board is formed with at least two, but most typically three, conductive material layers in which the data paths are formed. The first and second conductive layers are spaced apart by a single packer layer substrate and the second and third conductive layers are spaced apart by a single packer layer structure or by a substrate formed of a plurality of layers to allow the manufacture of the printed circuit board structure to be economical whilst allowing the quality of the data signals provided to be at least maintained. The connection between the waveguide and LNB is tuned at the waveguide with respect to the impedance values.

The invention to which this application relates is apparatus for the receipt of data which is transmitted via satellite transmission systems and, in particular, to apparatus in the form of a waveguide and the Low Noise Block (LNB) connected therewith. The waveguide and LNB are typically provided as part of apparatus which is provided at a location in conjunction with an antenna to allow data received from the antenna to be passed through the waveguide and LNB and passed on for subsequent processing via cable connection. The apparatus can be provided as an assembly, with the antenna provided with a mounting bracket to allow the same to be located to a support such as the face of a wall or a pole. The antenna is positioned so as to allow the reception of data signals at one or more frequency bands from one or more satellites and the reflection of the data signals towards the waveguide structure which is mounted, in conjunction with the LNB, at the free end of an arm protruding to the front of the antenna.

The required data signals are then passed from the antenna and through the waveguide feedhorn and onto the LNB via probe pins. The LNB typically includes an outer housing and one or more printed circuit boards mounted therein with data signal processing components located and/or formed thereon. The received data signals are processed as required and then passed to one or more outlets to be carried onwardly by the cable connection to one or more user locations. At the user location there is typically provided a broadcast data receiver or set top box via which a user can select to look at and/or listen to video and/or audio forming a television and/or radio programme which is decoded by the set top box using the appropriate portion or portions of the received data signals.

Typically the waveguide feedhorn, which forms part of the waveguide structure, will be integrated into the LNB housing and typically two polarisations of the received data signals will be required to be processed separately along different paths and the paths are provided and formed on the printed circuit board with appropriate components of the LNB. The polarisations may be horizontal and vertical or Left and Right Circular polarities. It is typically the case that the data processing paths will include one or more image reject filters in order to allow the required level of filtering of the data signals to remove unwanted signals and noise from the paths and thereby avoid potential degradation of the required data provision. The need to provide these filters, which can often be of significant size, and to form the same as part of the data signal paths on the printed circuit board, has meant that the dimensions of the printed circuit board and, in turn, the size of the LNB itself due to the increased size of the housing in which the printed circuit board is provided, are larger than desired. Furthermore, there is a need to provide relatively low loss dielectric characteristics which are required in order to ensure that the data passing along the paths including the filters is not subject to levels of loss which can cause unacceptable levels of data signal degradation. In order to achieve this conventionally the material used to form the printed circuit boards is required to be of relatively high specification so as to provide tight control over parameters such as dielectric constant, loss and dimensional tolerances and, as a result, the material used is a relatively expensive printed circuit board material. This, in turn, adds to the cost of the LNB in a price sensitive marketplace.

An example of the quality of printed circuit board material which is required to be used is that sold under the registered trade mark “Rogers 4000 series”.

These problems of size and cost are further exacerbated by the recent developments in LNB design in which, rather than all of the received data signals over the entire Ku band of 10.7 to 12.75 GHz being transmitted to the end user location from the LNB so that the set top box or broadcast data receiver then tunes to the required data portion for a television programme, it is now the case that a Digital Channel Stacking System (DCSS) integrated circuit (IC) can be provided at the LNB. This IC allows the processing of the received data signals to allow the selection, in response to a signal from the set top box representing a user programme selection, of the portion of data required for the particular user selected television programme. This portion of data is then transmitted via a dedicated output channel to the broadcast data receiver at the particular user location from which the selection was made. This DCSS IC has a number of output channels, such as 20 or more, and receives all of the wanted data signals emitted from the waveguide along the data paths of the printed circuit board.

Thus, when a user makes a selection of a particular television programme that they wish to watch, the portion or portions of data required to be received by the users set top box to allow that television programme to be generated is identified and a signal is sent back to the LNB, from the set top box. The DCSS IC therein is capable of obtaining the required portion of data from the received data signals, and directing that data portion to one of the output channels at an identified frequency which is, in turn, connected to the particular user location to allow the required data portion to be supplied for processing to the appropriate set top box from which the user selection was received. This process is then repeated independently, and as and when required, for requests received from each set top box at each of the user locations connected to the LNB. It will therefore be appreciated that the LNB at any given time may be directing different portions of received data to different user locations simultaneously from the respective outputs of the IC.

The need for the DCSS IC to have a large number of output channels and process multiple input signals means that when the same is connected to the printed circuit board a relatively large number of pins, such as 76, are required to be connected to the PCB and the operation of the IC requires a relatively high level of power and significantly more power than is required by a conventional LNB printed circuit board. Thus, at present, the skilled person faced with the problem of providing relatively high power supply to a large number of pins of the DCSS IC and being able to provide the required image reject filters formed on the printed circuit board would conventionally provide a multiple PCB assembly in which one of the boards is provided of the relatively expensive PCB material of the type previously indicated so that the image filters can be formed of a required quality thereon, and a second PCB is provided on which the DCSS IC can be located and the two boards are then interconnected. While this can provide a solution to the problem, it means that the overall size of the LNB is increased in order to accommodate the two boards and, when one considers that these LNB's are typically provided as large volume manufactured items, it will be appreciated that the cost of the same is a critical element.

An aim of the present invention is therefore to provide an LNB which allows the utilisation of a frequency conversion IC and a DCSS IC located therein in a manner which ensures the required performance level of the LNB is achieved whilst at the same time minimising the size and cost of the LNB. A further aim of the invention is to provide a waveguide and LNB assembly which provides advantages in terms of tuning and impedance matching of the data paths.

In a first aspect of the invention there is provided a Low Noise Block (LNB) apparatus, said LNB including input means to allow at least first and second components of received data signals to enter and pass along respective data processing paths formed on a printed circuit board structure, housed within the LNB, to an integrated circuit component with frequency translation capability and including at least one image rejection mixer or direct conversion mixer, said integrated circuit component provided to output selected portions of the received data via selected outputs therefrom and wherein the said printed circuit board structure includes first and second, spaced apart, conductive material layers, and said integrated circuit is mounted on the first of said layers which is spaced from the second of said layers by a packer substrate formed by a single layer of material.

In one embodiment the printed circuit board structure includes the said first and second spaced layers of conductive material and a third layer of conductive material which is spaced from the second layer of conductive material by a single or a plurality of layers of material and most typically the layer or layers are formed of pre-impregnated material (pre-preg) which, in one embodiment, is formed by fibreglass impregnated with resin.

In one embodiment the said packer substrate layer of material which spaces the first and second layers of conductive material apart is also formed of a pre-impregnated material provided as a single integral layer which is pre-impregnated fibreglass with resin rather than being formed from a number of layers joined together by resin.

In one embodiment the dielectric constant value of the single packer layer is more controllable than that of a plurality of layers being used. In one embodiment the spacing between the second and third layers of conductive material is formed by a plurality of layers.

Typically one or a plurality of said integrated circuits, if provided, is/are mounted on the first layer of conductive material and preferably those components of the data signal processing paths which are most susceptible to RF characteristics of the circuit board material are also mounted on the said first layer of conductive material.

In one embodiment the conductive layers are formed of, or includes, copper.

In one embodiment each of the data signal paths includes an LNA, also referred to as a FET which receives, in direct contact therewith, or is located adjacent thereto, a probe pin from a waveguide associated with the LNB so as to allow a component of the data signals received by the waveguide to pass along respective paths of the LNB.

Typically the probe pins pass through respective passages from the waveguide to the printed circuit board in the LNB and the tuning is achieved by altering at least one parameter of the probe pin and/or passages.

In one embodiment the parameter is any, or any combination, of the selection of the size of the respective passages and/or the selection of the sizes of the respective probes or pins and/or the selective provision of a sleeve of a dielectric material which is positioned around one of the probes or pins.

In one embodiment a first integrated circuit (IC) is provided with the facility to downconvert the frequency of the received data signals on both of said paths and thus a wideband LNB is formed.

In one embodiment a Digital Channel Stacking switch (DCSS) facility is also provided, as part of the first IC, or as a separate, second, IC. Typically, when the second IC is provided it is located downstream of the first IC with respect to the direction of flow of the data from the waveguide.

Typically the DCSS facility allows a selected portion of data to be transmitted from an output from the integrated circuit to pass to a broadcast data receiving apparatus from which a signal has been received indicating a programme selection for which the said portion of data is required. Typically a plurality of broadcast data receivers are provided, each connected to a separate pin of the DCSS facility and each independently receives a portion of data which is relevant to a programme selection made by the respective broadcast data receiver.

Preferably the printed circuit board is located in the LNB with respect to the probe pins from the waveguide such that the length of the data path from the probe pin to the first component downstream on the data path, such as in the form of the LNA or Field Effect Transistor (FET), is as short as possible so as to minimise losses in the data signal which may occur prior to the data signals reaching the component and, in turn, the down conversion integrated circuit.

In one embodiment a single integrated circuit is used to downconvert the frequency of all of the data signals which are received and this also includes a digital channel stacking switch DCSS facility to allow selected portions of data to be output from respective output pins for passage to selected user location apparatus.

Alternatively, a downconverter IC and a separate DCSS facility IC are provided to receive data from both data paths.

The fact that the image reject mixer or direct conversion mixer is provided as an integral part of the down conversion integrated circuit allows the potential for signals and/or noise from unwanted frequency bands to be reduced or eliminated and thereby allows any degradation of the wanted frequency band data signals to be at an acceptable level. In typical applications 40 dB rejection is required to achieve this. In one embodiment up to −40 dB filtering can be achieved by the mixer of the integrated circuit.

The ability to achieve this level of filtering in the down conversion integrated circuit means that it is no longer necessary to rely entirely on image rejection provided by the frequency response of the other LNB components and so no image reject filters are required on the printed circuit board. This therefore means that the size of the printed circuit boards and hence the expense of the same can be reduced. Typically, the impact of the waveguide structures and LNA frequency response as part of the data signal paths is reduced.

Furthermore, as the image reject filters are no longer required to be formed separately on the data paths of the printed circuit board, so the size of the printed circuit board is reduced as it is no longer necessary to accommodate the relatively large surface area required by the filters thereon.

The provision of the printed circuit board with the structure as herein described also means that the use of the relatively expensive printed circuit board material is no longer required and more economical materials such as Fire Retardant (FR4) material can be used to form the printed circuit board.

In one embodiment the material which is used to form the printed circuit board structure has a dielectric constant value in the range of 5.0+/−1.

In a further aspect of the invention there is provided a printed circuit board structure comprising first, second and third spaced apart layers of conductive material, wherein the first and second layers are spaced apart by a single packer substrate layer formed of a pre-impregnated material and the second and third layers are spaced apart by a substrate formed by a single layer or a plurality of layers of pre-impregnated material.

Typically the tolerance of the impedance value of the single packer layer can be more closely controlled for each printed circuit board than the spacing formed by the plurality of pre-preg layers due to the fact that the packer is a single layer formed as a unitary member and hence the potential variation in thickness of the manufacture of the same is reduced in comparison to the case where a plurality of layers are joined together and each of the layers has a potential variation in thickness and/or material characteristics.

In a further aspect of the invention there is provided a Low Noise Block (LNB) apparatus, said LNB including input means to allow data on first and second data signal components to enter the LNB and pass along respective data paths formed on a printed circuit board structure to an integrated circuit component with frequency translation capability and which printed circuit board structure includes at least one image rejection mixer or direct conversion mixer and data is output from the printed circuit board structure via selected outputs from the integrated circuit components and wherein the filtering of unwanted data frequency bands from the received data signals is performed using the at least one image rejection mixer or direct conversion mixer of the said integrated circuit.

In a further aspect of the invention there is provided a waveguide and LNB assembly including a printed circuit board structure including first and second conductive layers spaced apart by a single substrate of pre impregnated material, first and second data paths are formed on a first of the conductive layers, said waveguide located in a fixed position with respect to the LNB such that probe pins leading from the waveguide pass through respective passages in an interface between the waveguide and LNB to contact with the respective data paths on the printed circuit board structure at, or adjacent to, a component in the form of an LNA or FET on the respective data paths.

In a yet further aspect of the invention there is provided a method of forming a waveguide and LNB assembly, said method comprising the steps of providing a printed circuit board structure in the LNB, forming first and second data paths on the printed circuit board, each of which includes an LNA or FET, providing a waveguide in fixed position with respect to the LNB such that probes or pins leading from the waveguide contact with respective data paths on the printed circuit board structure, said probes or pins passing through respective passages to contact with the respective data paths at or adjacent to the respective LNA's or FET's and wherein a tuning step is performed at the waveguide with respect to at least one of the probe pins, if necessary, to match the impedance values and the tuning step includes altering a parameter of at least one of the probe pins and/or passages.

In one embodiment the tuning includes any, or any combination of

(i) the selection of the size of the passages; and/or

(ii) the selection of the sizes of the respective probe pins and/or

(iii) the selective provision of a sleeve of a dielectric material which is positioned around one of the pins.

Specific embodiments of the invention are now described with reference to the accompanying drawings; wherein

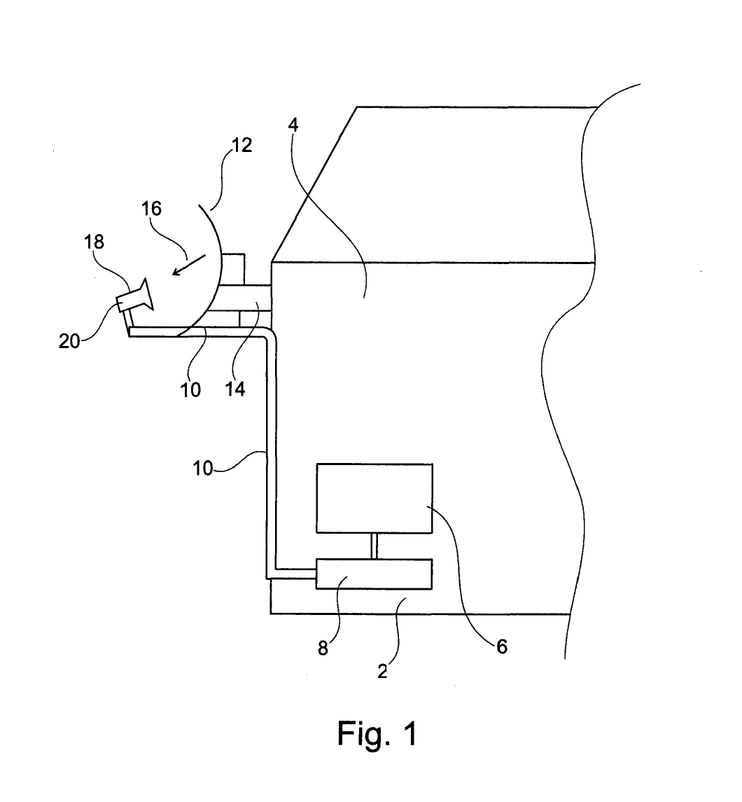

FIG. 1 illustrates in a schematic manner the components of receiving apparatus for satellite transmitted data in accordance with one embodiment of the invention;

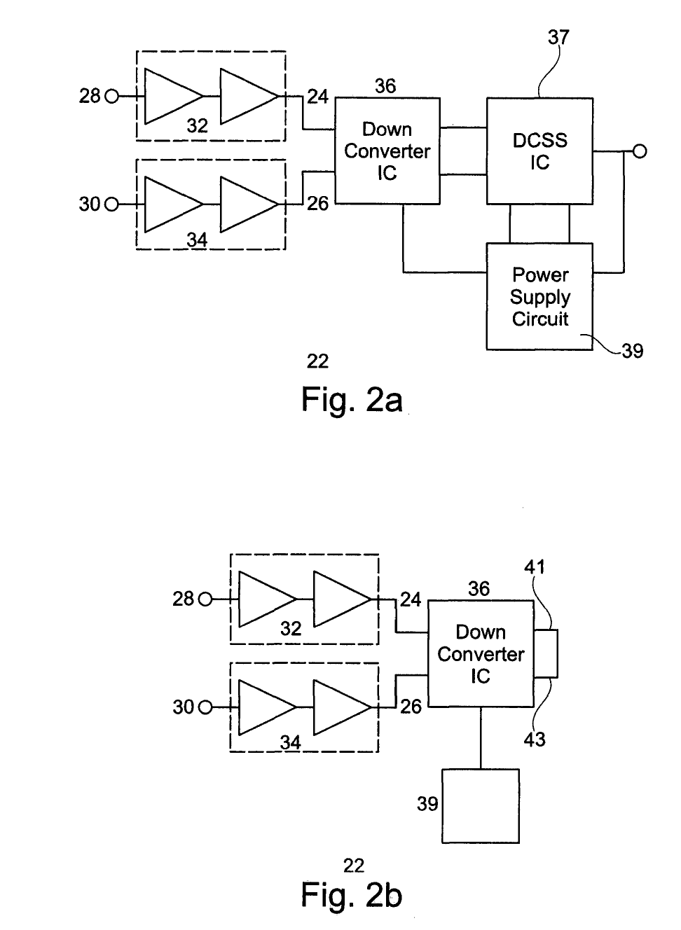

FIGS. 2a and b illustrate block diagram views of a printed circuit board layout in accordance with first and second embodiments of the invention;

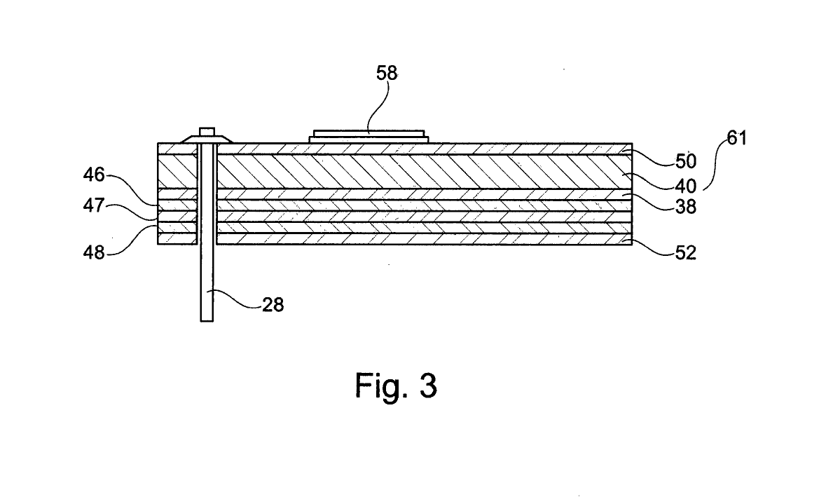

FIG. 3 illustrates a cross sectional elevation of a printed circuit board structure in accordance with one embodiment of the invention;

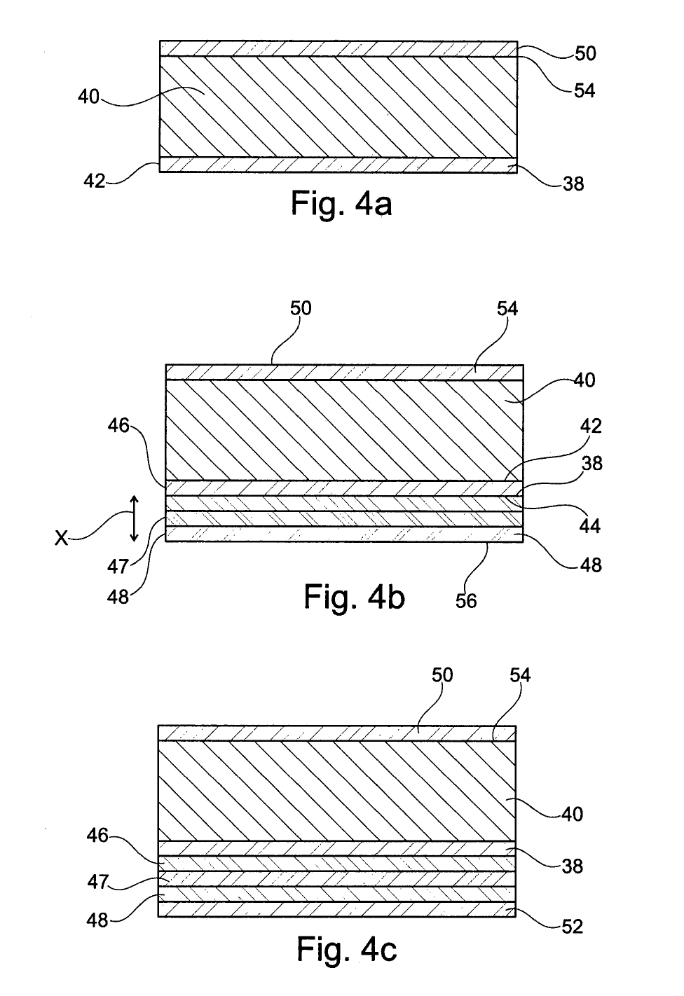

FIGS. 4a-c illustrate the steps which may be followed in the formation of the printed circuit board structure of FIG. 3;

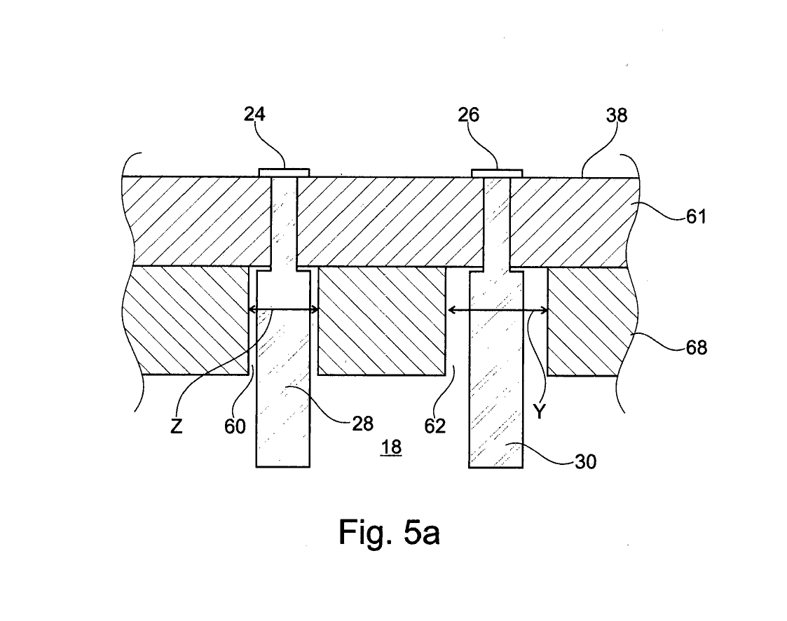

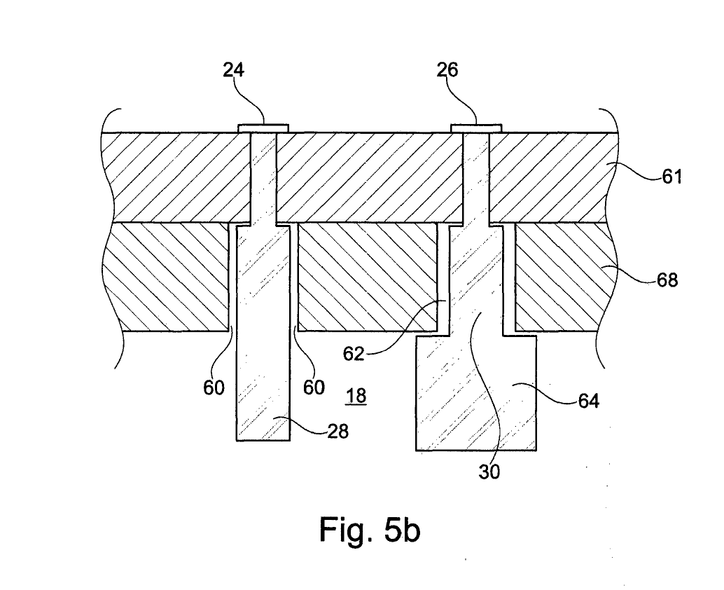

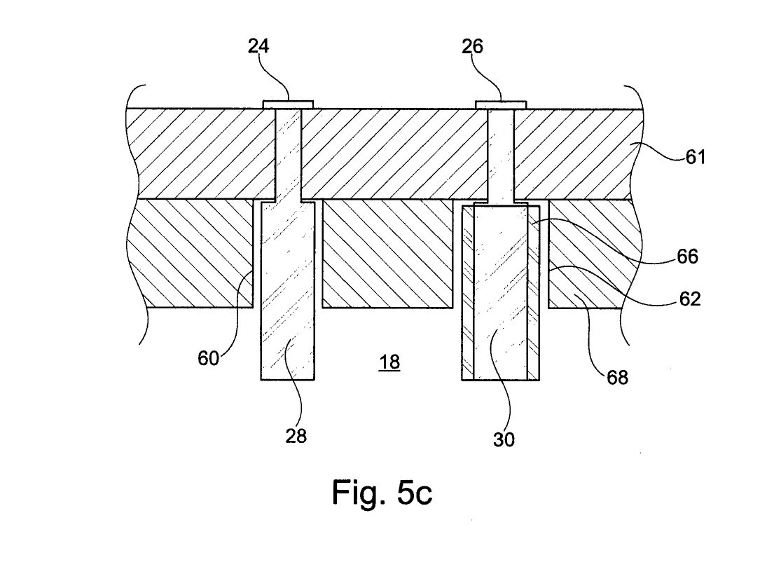

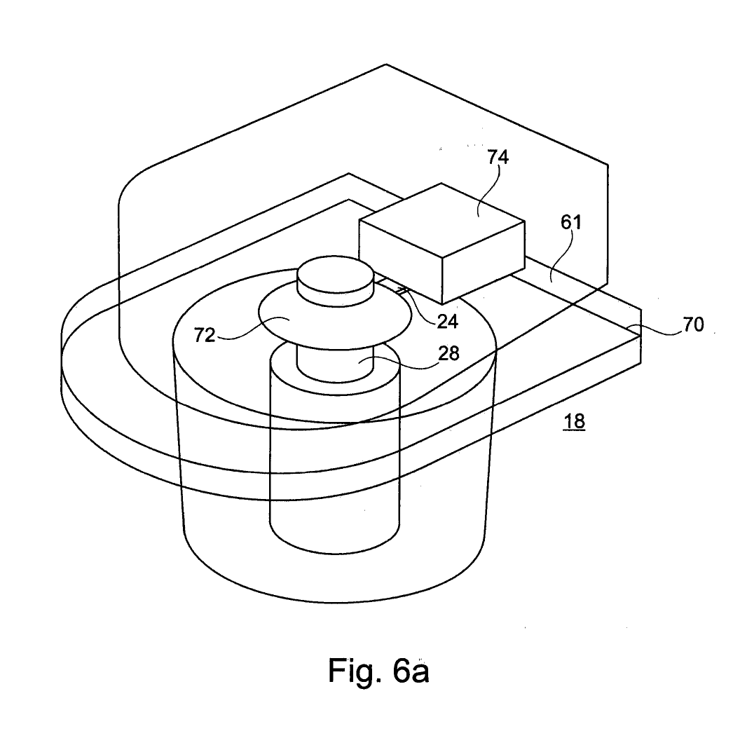

FIGS. 5a-c illustrates a cross sectional elevation of the interface between the waveguide probes and the printed circuit board in accordance with one embodiment of the invention; and

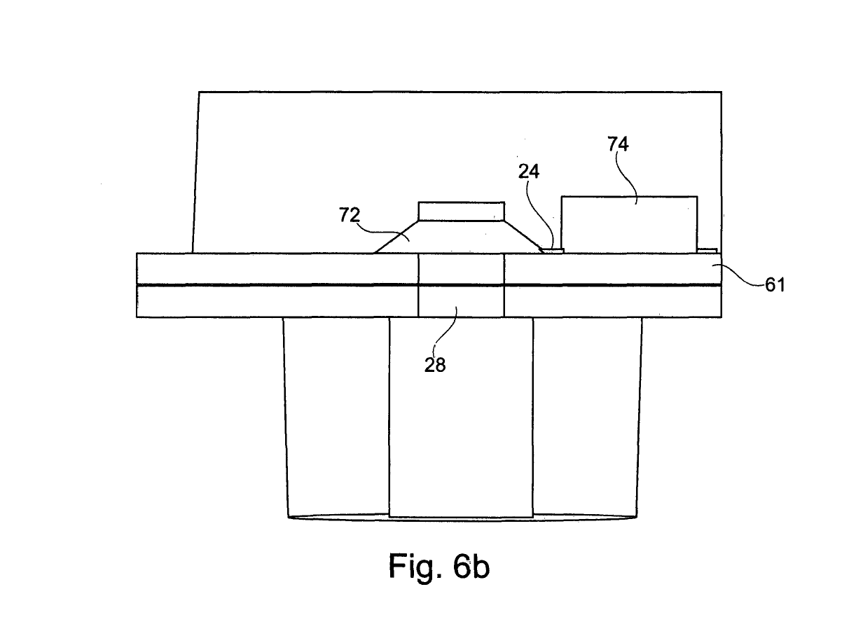

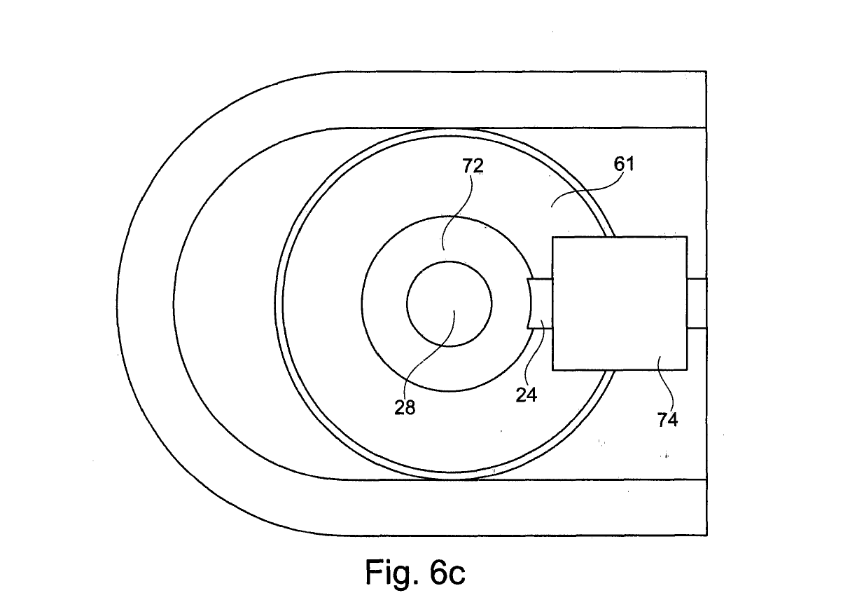

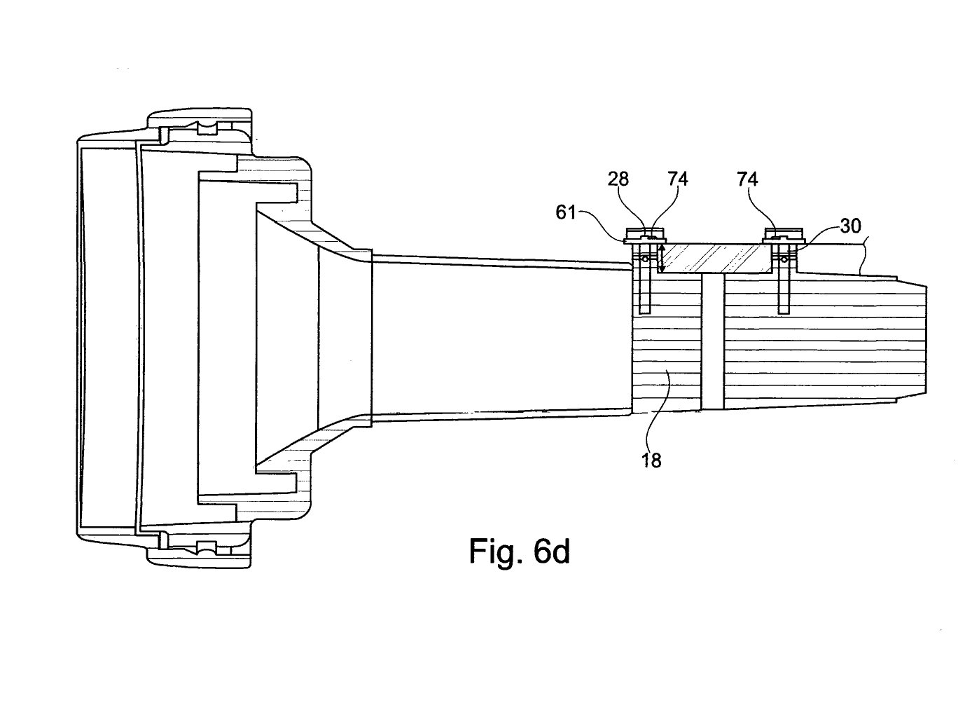

FIGS. 6a-c illustrate views of one embodiment of the interface between the FET on the PCB and a probe pin from the waveguide.

FIG. 1 illustrates in a schematic manner the apparatus which is typically provided to receive data which is transmitted via a satellite transmission system. The apparatus allows the provision of data to a user location 2 in the form, typically, of a room of domestic or business premises 4. Within the premises there are typically provided a display screen and speakers 6 connected to a broadcast data receiver or set top box 8 which acts in a conventional manner to receive and process portions of data to allow the generation of television and/or radio programmes via the display screen and speakers following a user selection.

The data is received via cable connection 10 from apparatus mounted externally of the premises and which apparatus includes an antenna 12 with mounting bracket 14 to secure the antenna at a required position so as to be able to receive data signals from one or more satellites which, for example, is transmitted in the Ku band. The received data signals are reflected from the antenna as indicated by arrow 16 to a feedhorn of waveguide 18 which passes the wanted data signals via probe pins to an LNB 20 provided to the rear of the waveguide. The LNB then passes the required portions of data for selected programmes via the cable connection 10.

Turning now to FIGS. 2a and b there are provided two embodiments of apparatus in accordance with the invention. In FIG. 2a there is provided a plan view of a printed circuit board arrangement provided within the LNB in accordance with the invention in one embodiment. The printed circuit board 22 includes two data signal paths 24, 26 for receiving data signal components from respective probe pins 28, 30 which depend from the waveguide to contact with respective Low Noise amplifiers (LNA) or FET's 32, 34 formed and/or located on the printed circuit board conductive layer. The paths then continue to a down converter integrated circuit IC 36 and then to a DCSS IC 37 from which data portions can be supplied as required to the broadcast data receivers connected to the DCSS IC. A power supply 39 is also provided.

In FIG. 2b there is provided a second embodiment in which a wideband LNB is formed and the components which are common to FIG. 2a are provided with the same reference numerals. However in this case it will be noted that no DCSS IC 37 is provided and instead the two output paths 41, 43 are the outputs from the LNB.

It should be appreciated that in both embodiments the advantages of being able to use a reduced size and cost of printed circuit board structure are achieved as the one or more image reject mixers, (also referred to as direct conversion mixers) which allow unwanted frequency bands of data signals to be filtered out and hence allow the required frequency band to be available, are provided in the down conversion IC 36 rather than as separate components as would conventionally be the case.

The integrated circuits are of a form which allows, in the first IC 36, the down conversion of the data signals frequency band and then, in the embodiment of FIG. 2a, in the second IC 37, digitally, the stacking of the data signals and the selection of portions of data which are required in order to allow a particular programme to be generated. The particular programme is that which has been selected by the user at the user location 2 and a signal representing the same has been transmitted to the DCSS integrated circuit 37. When the appropriate data is selected from the digital stack by the integrated circuit 37 the same is output via a pin of the integrated circuit 37 at an identified frequency such that the set top box 8 at the user location 2 can tune to and process the said portion of data from that pin in order to process the same and generate the required programme. Typically, all of the output channels are combined inside the IC 37 onto a single output in a stacked manner or, as in this case, where there are different paths, so two outputs are used for the output signals.

In addition, and as previously indicated, the down converter integrated circuit 36 includes one or more image reject mixers, (also referred to as direct conversion mixers) which allow unwanted frequency bands of data signals to be filtered out and hence allow the required frequency band to be available. The filtering which is required typically needs to be in the region of 40 dB.

In order to minimise the cost of the LNB there is a need to reduce the size of the LNB as much as possible and preferably to reduce the cost of the materials used, whilst maintaining the ability of the LNB to operate correctly and provide the required quality of signal processing. These aims are achieved in the current invention by the recognition that the image rejection mixers of the integrated circuit 36 are capable and can be used to provide the required data signal filtering and thereby avoid the need for image rejection filters to be provided on the printed circuit boards and, as these filters would typically be required to take up a significant area of printed circuit board, so the size of the printed circuit board which is required in accordance with the invention is reduced.

Furthermore, as indicated in FIGS. 3 and 4a-c a printed circuit board structure in accordance with the invention means that the materials used for the printed circuit board can be relatively low cost materials in comparison to the higher cost printed circuit broad materials that would conventionally be used. This means that materials which have a higher dielectric or loss characteristic can be used than would conventionally be possible, whilst the structure ensures that the relatively tight tolerance levels in terms of performance of each LNB which is manufactured using the printed circuit board structure in accordance with the invention can still be achieved. An advantage of being able to use cheaper, higher dielectric constant material is that it allows for a reduction in the printed circuit board size due to the increased physical scaling of components afforded by using the higher dielectric constant material.

Referring now to FIGS. 3 and 4a-c there is illustrated the method steps which can be followed to form a printed circuit board structure in accordance with one embodiment of the invention, with the views showing an end elevation of the layers of the printed circuit board structure.

In FIG. 4a there is shown a conductive layer 38 of copper formed on a face 42 of a packer layer 40 which is a unitary item typically formed of resin impregnated glass fibre. The conductive layer 50 can also be provided at this stage on the opposing face 54 of the packing layer 40.

FIG. 4b illustrates the next possible step and on the face 44 of the copper layer 38, there is applied one, but more typically a series of layers 46, 47, 48 of pre preg material, which again can be resin impregnated glass fibre. These could be provided as a unitary layer of the required thickness but more typically a number of layers of the pre-preg material are combined to form the spacing of the required thickness X and which can be achieved by selecting the layers of predetermined thickness.

FIG. 4c illustrates the manner in which a further conductive layer 52, again typically of copper or containing copper, is applied to the outer face 56 of the structure of FIG. 4b to form a printed circuit board. In this case therefore the structure has three conductive layers 50, 38 and 52 but could be used with just two of the conductive layers to advantage.

The completed printed circuit board structure 61 in one embodiment is illustrated in FIG. 3 in end elevation and it will be seen that an integrated circuit 58 is shown and this could be a combined down conversion and DCSS facility integrated circuit or could be one of the Integrated circuits 36, 37 from FIGS. 2a and b. If the printed circuit board structure was used from the embodiment shown in FIG. 2a then a second integrated circuit would also be provided in contact with the conductive material layer 50.

Typically, all components and formations on the data paths which are particularly sensitive to RF properties of the substrate material will be located or formed on the first conductive layer 50. The probe pins, one of which is shown, pin 28, are connected to the layer 50 using via passages which pass through the printed circuit board material. The intermediate or second conductive material layer 38 is utilised as an RF ground layer and the third layer conductive material layer 52 may typically be used for further component connections.

As the spacing between the layers 50 and 38 is achieved via the single packer layer 40 which may, for example be of a thickness of 0.3 mm, so the thickness of this layer can be more closely controlled and therefore is best suited to act as an RF interface layer and in which the dielectric constant value can be more closely controlled due to improved tolerance control during manufacture of the material.

The dimensions of the spacing between the layers 38 and 52 need not be as closely controllable due to the fact that each of the plurality of layers will have their own tolerance values and which, when the layers are combined, will mean that there is less control of the thickness of the overall spacing between the layers 38 and 52. However as the RF sensitive components are not mounted, or formed, on the conductive material layers 38 and 52, so the reduced level of control of the spacing is not an issue and so the cheaper material and multi-layered structure can be used without affecting the performance of the printed board structure.

As previously mentioned, the LNB is provided to be used in conjunction with a waveguide 18, an example of which for Ku frequency data signals is shown in FIG. 6d, and from which depends the first and second probe pins 28,30. The probe pins are provided to contact with respective data signal paths 24, 26 on the printed circuit board conductive layer 38 of the structure 61 and allow the transfer of data signals received from the satellite antenna with respect to which the waveguide and LNB are mounted. The printed circuit board 61 is mounted such that the probes can contact directly or adjacent to the components on the respective data paths such as the LNA's or field effect transistors (FET's) 32,34, one of which is shown as reference numeral 66 in FIGS. 6a-c and located on the printed circuit board conductive layer 38. This means that losses in the data signal which may occur prior to the data signals reaching the component 32, 34, 66 are minimised.

Furthermore, in accordance with the invention in one embodiment, the data paths 24,26 can be tuned so as to match the impedance of the same by performing the tuning at the probe pins at the waveguide rather than on the data paths on the conductive layer. The ability to tune at the probe pins locations overcomes the need for tuning on the PCB paths. This is of advantage as tuning on the printed circuit board is problematic due to the lack of available space on the paths between the location of the probe pins and the respective component 32, 34; 66 on the data path.

The tuning is therefore performed, most typically at the time of assembly, so that the data signals carried along the respective data paths 24, 26 are matched in terms of impedance. FIGS. 5a-c illustrate the manner in which the probes 28,30 pass from the waveguide 18 through respective passages 60, 62 in the LNB housing wall 68 and into contact through the printed circuit board structure 61 to the conductive surface 38 on which the data paths 24, 26 are formed.

In accordance with this embodiment the tuning can be achieved in a number of ways via the probe pins and examples of the tuning steps which can be performed include any or any combination of:

(i) the selection of the size of the passages 60,62 so that, for example one of the passages 60 may be formed with a different diameter Z than the diameter Y of the other passage 62 so as to provide the tuning effect and the matching of the two data paths and as shown in FIG. 5a; and/or

(ii) the selection of the sizes of the respective probe pins 28,30 so that, for example, one of the pins 28 may be of a different dimension to the other of the probe pins, perhaps by providing the same with a stub portion 64, so as to provide a tuning effect and the matching of the two data paths and as shown in FIG. 5b; and/or

(iii) the selective provision of a sleeve 66 of a dielectric material which is positioned around one of the pins 30 so as to provide the tuning effect and the matching of the two data paths as shown in FIG. 5c.

The ability to provide the tuning of the data paths at and within the waveguide/printed circuit board assembly 61 interface is an improvement on trying to provide the matching of the data paths on the printed circuit board itself and allows the components on the data paths to be more closely located to the probe pins and thereby achieve the advantages associated with that.

FIGS. 6a-c illustrate an example of the interface between one of the probe pins 28 and the printed circuit board assembly 61. It is shown how the probe pin 28 passes from the waveguide 18 and through the wall 70 of the waveguide/LNB interface to reach a cap formation 72 which is located to contact with a data path 24 formed on the conductive layer 38 of the assembly 61. In accordance with the invention the next component on the data path, in this case the FET or LNA 74 can be located very close to the cap 72 of the probe so as to minimise the length of the path 24 portion in which loss or interference can occur

1. A Low Noise Block (LNB) apparatus, said LNB including input means to allow at least first and second components of received data signals to enter and pass along respective data processing paths formed on a printed circuit board structure, housed within the LNB, to an integrated circuit component with a down conversion frequency translation facility and including at least one image rejection mixer or direct conversion mixer, said integrated circuit component provided to output selected portions of the received, data via selected outputs therefrom and wherein the said printed circuit board structure includes first and second, spaced apart, conductive material layers, and said integrated circuit is mounted, on the first of said conductive layers which is spaced from the second of said conductive layers by a packer substrate formed by a single layer of material and said first conductive layer is formed on a first face of the said packer substrate and the said second conductive layer is formed on the opposing face of the said packer substrate.

2. Apparatus according to claim 1 wherein the printed circuit board structure includes a third layer of conductive material which is spaced from the second layer of conductive material by a substrate formed by a single or a plurality of layers of material.

3. Apparatus according to claim 2 wherein the said layers are formed of pre-impregnated (pre-preg) material.

4. Apparatus according to claim 2 wherein when a plurality of layers are provided the same are adhered together using a resin.

5. Apparatus according to claim 1 wherein the said packer substrate is formed by a single layer comprising fibreglass impregnated with a resin.

6. Apparatus according to claim 3 wherein the dielectric constant value of the said single layer packer substrate which spaces the first and second conductive material layers is more controllable than the substrate formed by a plurality of layers to space the second and third conductive layers.

7. Apparatus according to claim 1 wherein the said substrates used to space the conductive layers apart has a dielectric constant value in the range of 5.0+/−1.

8. Apparatus according to claim 1 wherein those components of the data signal processing paths which are susceptible to interference by RF characteristics of the printed circuit board structure are mounted on, and in contact with, the said first layer of conductive material.

9. Apparatus according to claim 1 wherein the conductive material layers are formed of, or at least include, copper.

10. Apparatus according to claim 1 wherein the LNB is used in conjunction with a waveguide and connected thereto via first and second probe pins which pass from the waveguide to the LNB and through which the data signals are received so as to allow respective data signal components from the respective probe pin to be passed along respective paths of the LNB.

11. Apparatus according to claim 10 wherein each of the two data signal paths in the LNB include an LNA and FET which are connected by the said respective paths to a respective probe pin.

12. Apparatus according to claim 11 wherein the printed circuit board structure is located in the LNB such that the probe pins contact directly with or adjacent to the respective LNA and/or FET location on the printed circuit board structure.

13. Apparatus according to claim 10 wherein the probe pins are tuned with regard to their impedance so that the data signals on the respective data paths are matched.

14. Apparatus according to claim 13 wherein the probe pins pass through respective passages from the waveguide to the printed circuit board in the LNB and the tuning is achieved by altering at least one parameter of the probe pin and/or passages.

15. Apparatus according to claim 14 wherein the parameter is any, or any combination, of the selection of the size of the respective passages and/or the selection of the sizes of the respective probes Or pins and/or the selective provision of a sleeve of a dielectric material which is positioned around one of the probes or pins.

16. Apparatus according to claim 1 wherein a first integrated circuit (IC) is provided to downconvert the frequency of the received data signals on both of said paths.

17. Apparatus according to claim 16 wherein the LNB is a wideband LNB.

18. Apparatus according to claim 16 wherein a Digital Channel Stacking switch (DCSS) facility is provided as part of the first IC or as a separate, second, IC.

19. Apparatus according to claim 18 wherein the second IC, when provided, is located downstream of the first IC with respect to the direction of flow of the data from the waveguide.

20. Apparatus according to claim 18 wherein the DCSS facility allows a selected portion of data to be transmitted from an output from the integrated circuit to pass to a broadcast data receiving apparatus from which a signal has been received indicating a programme selection for which the said portion of data is required.

21. Apparatus according to claim wherein a plurality of broadcast data receivers are each connected to a separate pin of the DCSS facility and each independently receives a portion of data which is relevant to a programme selection made by the respective broadcast data receiver.

22. Apparatus according to claim 18 wherein the first, and when provided, second, integrated circuits are mounted on the first conductive material layer,

23. Apparatus according to claim 1 wherein the image reject mixer or direct conversion mixer reduces signals and/or noise from unwanted frequency bands of the received data.

24. Apparatus according to claim 23 wherein the mixer achieves substantially 40 dB rejection.

25. A printed circuit board structure comprising first, second and third spaced apart layers of conductive material, wherein the first and second layers are spaced apart by a single packer substrate layer formed of a pre-impregnated material and said first conductive layer is formed on a first face of the said single packer substrate layer and the said second conductive layer is formed on the opposing face of the said single packer substrate layer and the second and third layers are spaced apart by a further substrate formed by one or a plurality of layers of pre-impregnated material.

26. A low Noise Block (LNB) apparatus, said LNB including input means to allow data on first and second data signal components to enter the LNB and pass along respective data paths formed on a printed circuit board structure to an integrated circuit component with frequency translation capability and which printed circuit board structure includes at least one image rejection mixer or direct conversion mixer and data is output from the printed circuit board structure via selected outputs from the integrated circuit components and wherein the filtering of unwanted data frequency hands from the received data signals is performed using the at least one image rejection mixer or direct conversion mixer which is provided integrally with the said integrated circuit.

27. Apparatus according to claim 26 wherein a digital channel stacking facility is provided integrally with the said integrated circuit or in a second integrated circuit.

28. A waveguide and LNB assembly including a printed circuit board structure including first and second conductive layers spaced apart by a single substrate of pre impregnated material, first and second data paths are formed on a first of the conductive layers, said waveguide located in a fixed position with respect to the LNB such that probe pins leading from the waveguide pass through respective passages in an interface between the waveguide and LNB to contact with the respective data paths on the printed circuit board structure at, or adjacent to, a component in the form of an LNA or FET on the respective data paths and said first conductive layer is formed on a first face of the said single substrate and the said second conductive layer is formed on the opposing face of the said single substrate.

29. A method of forming a waveguide and LNB assembly, said method comprising the steps of providing a printed circuit board structure in the LNB, forming first and second data paths on the printed circuit board, each of which includes an LNA and/or FET, providing a waveguide in fixed position with respect to the LNB such that probes or pins leading from the waveguide contact with respective data paths on the printed circuit board structure, said probes or pins passing through respective passages to contact with the respective data paths at or adjacent to the respective LNA's or FET's and wherein a tuning step is performed at the waveguide with respect to at least one of the probe pins, if necessary, to match the impedance values and the tuning step includes altering a parameter of at least one of the probe pins and/or passages.

30. A method according to claim 29 wherein the tuning includes any, or any combination of
(i) the selection of the size of the passages; and/or
(ii) the selection of the sizes of the respective probe pins and/or
(iii) the selective provision of a sleeve of a dielectric material which is positioned around one of the pins.

31. Apparatus according to clam 1 wherein the said received data signals at the LNB are in the Ku band.
